(19) United States
(12) Patent Application Publication
(10) Pub. No.: US 2024/0321987 A1
(43) Pub. Date: Sep. 26, 2024

(54) LONG CHANNEL FIN TRANSISTORS IN NANORIBBON-BASED DEVICES

(71) Applicant: Intel Corporation, Santa Clara, CA (US)

(72) Inventors: Tao Chu, Portland, OR (US); Guowei Xu, Portland, OR (US); Robin Chao, Portland, OR (US); Chiao-Ti Huang, Portland, OR (US); Feng Zhang, Hillsboro, OR (US); Minwoo Jang, Portland, OR (US); Chia-Ching Lin, Portland, OR (US); Biswajeet Guha, Hillsboro, OR (US); Yue Zhong, Portland, OR (US); Anand S. Murthy, Portland, OR (US)

(73) Assignee: Intel Corporation, Santa Clara, CA (US)

(21) Appl. No.: 18/187,990

(22) Filed: Mar. 22, 2023

(51) Int. Cl. H01L 29/423; H01L 27/088; H01L 29/06; H01L 29/66; H01L 29/775; H01L 29/78; H01L 29/786

(52) U.S. Cl. CPC H01L 29/42392; H01L 27/0886; H01L 29/0673; H01L 29/66439; H01L 29/66795; H01L 29/775; H01L 29/785; H01L 29/78696

(57) ABSTRACT

Described herein are integrated circuit devices that include both nanoribbon-based transistors and fin-shaped transistors. The nanoribbon transistors may have shorter channel lengths than the fin transistors. In addition, the nanoribbon transistors may have thinner gate dielectrics than the fin transistors.

### TECHNICAL FIELD

This disclosure relates generally to the field of integrated circuit (IC) structures and devices, and more specifically, to integrated circuit devices that include thick-gate fin-based transistors along with nanoribbon-based transistors.

### BACKGROUND

Gate all around (GAA) transistors, also referred to as surrounding-gate transistors, have a gate material that surrounds a channel region on all sides. GAA transistors may be nanoribbon-based or nanowire-based, and they can also be referred to as nanoribbon transistors or a nanowire transistors. In a nanoribbon transistor, a gate stack that may include one or more gate electrode materials and a gate dielectric may be provided around a portion of an elongated semiconductor structure called “nanoribbon”, forming the gate stack on all sides of the nanoribbon. A source region and a drain region can be provided on the opposite ends of the nanoribbon, on either side of the gate stack, forming, respectively, a source and a drain of such a transistor. Other transistors based on non-planar architecture include fin-shaped transistor devices, also referred to as FinFETs.

In some nanoribbon device fabrication processes, semiconductor nanoribbons are released from a surrounding supportive material, and the gate stack is regrown around the semiconductor nanoribbons to form a gate. For especially long nanoribbon channels, this process can cause structural issues in the nanoribbons, e.g., leading to bending or sagging in the channel material.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a cross-section across a long-channel nanoribbon-based transistor showing the source, gate, and drain, according to some embodiments of the present disclosure.

FIG. 1B is a cross-section across a short-channel nanoribbon-based transistor showing the source, gate, and drain, according to some embodiments of the present disclosure.

FIG. 2 is a cross-section of layers of alternating materials, according to some embodiments of the present disclosure.

FIG. 3 is a cross-section of the layers of alternating materials with a region removed, according to some embodiments of the present disclosure.

FIG. 4 is a cross-section illustrating a semiconductor material deposited next to the layers of alternating materials, according to some embodiments of the present disclosure.

FIG. 5 is a cross-section illustrating etched rows of the semiconductor material and stacks of alternating materials, according to some embodiments of the present disclosure.

FIG. 6 is a cross-section illustrating dielectric fill in the support structure, according to some embodiments of the present disclosure.

FIG. 7 is a cross-section illustrating deposition of thick gate dielectric and gate electrode material, according to some embodiments of the present disclosure.

FIG. 8 is a cross-section illustrating the release of nanoribbons from the stacks of alternating materials, according to some embodiments of the present disclosure.

FIG. 9 is a cross-section illustrating deposition of thin gate dielectric and gate electrode material around the nanoribbons, according to some embodiments of the present disclosure.

FIG. 10 is a cross-section illustrating different gate materials for different devices, according to some embodiments of the present disclosure.

FIG. 11 is a cross-section illustrating differing widths for fin and nanoribbon structures, according to some embodiments of the present disclosure.

FIG. 12 illustrates a cross-section of the fins and nanoribbons through the plane AA′ in FIG. 11, according to some embodiments of the present disclosure.

FIG. 13 illustrates a cross-section of two nanoribbon transistors through the plane BB′ in FIG. 12, according to some embodiments of the present disclosure.

FIG. 14 illustrates a cross-section of a fin transistor through the plane CC′ in FIG. 12, according to some embodiments of the present disclosure.

FIGS. 15A and 15B are top views of a wafer and dies that include one or more fin transistors along with nanoribbon transistors in accordance with any of the embodiments disclosed herein.

FIG. 16 is a cross-sectional side view of an IC device that may include one or more fin transistors along with nanoribbon transistors in accordance with any of the embodiments disclosed herein.

FIG. 17 is a cross-sectional side view of an IC device assembly that may include one or more fin transistors along with nanoribbon transistors in accordance with any of the embodiments disclosed herein.

FIG. 18 is a block diagram of an example computing device that may one or more fin transistors along with nanoribbon transistors in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Described herein are IC devices that include nanoribbon-based transistors with thin gate oxides and/or relatively short channel lengths, and fin-based transistors with thicker gate oxides and/or relatively long channel lengths. Nanoribbon-based transistors provide several advantages over other transistor architectures. For example, nanoribbon transistors provide improved electrostatic transistor control and faster transistor speeds relative to other transistor architectures. In addition, nanoribbon-based channels provide increased drive current at smaller scales relative to other nonplanar architectures, such as fin-shaped channels.

Transistors typically include a gate stack coupled to a semiconductor channel, such as a nanoribbon or a stack of nanoribbons. A gate stack includes a gate electrode and a gate dielectric, with the gate dielectric formed between the gate electrode and the channel material. In a nanoribbon transistor, the gate dielectric is formed around each nanoribbon, and the gate electrode is formed over and around the gate dielectric, including in spaces between adjacent nanoribbons in the stack. If the gate electrode is not present between adjacent nanoribbons, or only a small amount of gate electrode material is present, it can reduce device performance.

Current fabrication techniques for nanoribbon-based transistors can lead to defects in certain transistor structures. For example, during fabrication, semiconductor nanoribbons are typically “released” from a surrounding supportive material, and gate dielectric and gate metal are regrown around the semiconductor nanoribbons to form a gate. For long nanoribbon channels, this process can cause structural issues in the nanoribbons, e.g., leading to bending or sagging in the channel material. In addition, for very thin and tightly spaced nanoribbons (e.g., a stack of nanoribbons each around 4 nanometers high, with spaces of 10-15 nanometers between adjacent nanoribbons), a thick gate dielectric (e.g., 4-6 nanometers) consumes most or all of the space between the nanoribbons, leaving little or no space for the gate electrode to form between the nanoribbons. If the nanoribbons bend or sag during processing, this can further reduce the space between adjacent nanoribbons, e.g., if an upper nanoribbon sags more than a lower nanoribbon.

As described herein, fin transistors are used in combination with nanoribbon transistors in an IC device. The fin transistors can be used for applications that may lead to structural defects for nanoribbons transistors, e.g., to provide transistors with relatively thick gates (and, in particular, relatively thick gate oxides), and/or to provide transistors that have relatively long channel lengths and gate lengths. The fin transistors and nanoribbon transistors may be in the same device layer.

To form a device with nanoribbon-based transistors, a set of layers of alternating materials may be formed, where one of the materials is the channel material (e.g., silicon), and the other material is a sacrificial material that is removed and replaced with the gate dielectric and gate electrode. For example, the sacrificial material may be silicon germanium, which enables sequential epitaxial growth with the silicon channel material. The layers of alternating material are etched into rows to form nanoribbon channels.

To produce fin transistors, regions of the alternating materials for forming the nanoribbons are removed and replaced by a semiconductor material (e.g., silicon), which is then formed into fins. A portion of the newly grown semiconductor material adjacent to the nanoribbon materials may have defects, and this area may be removed when patterning the fins, so that the fins are relatively free of defects. The fins may be used to produce transistors with different specifications from transistors formed over the nanoribbons, e.g., with different gate lengths or different gate oxide thicknesses.

The fin transistors and nanoribbon transistors described herein may be implemented in one or more components associated with an IC. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g. logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

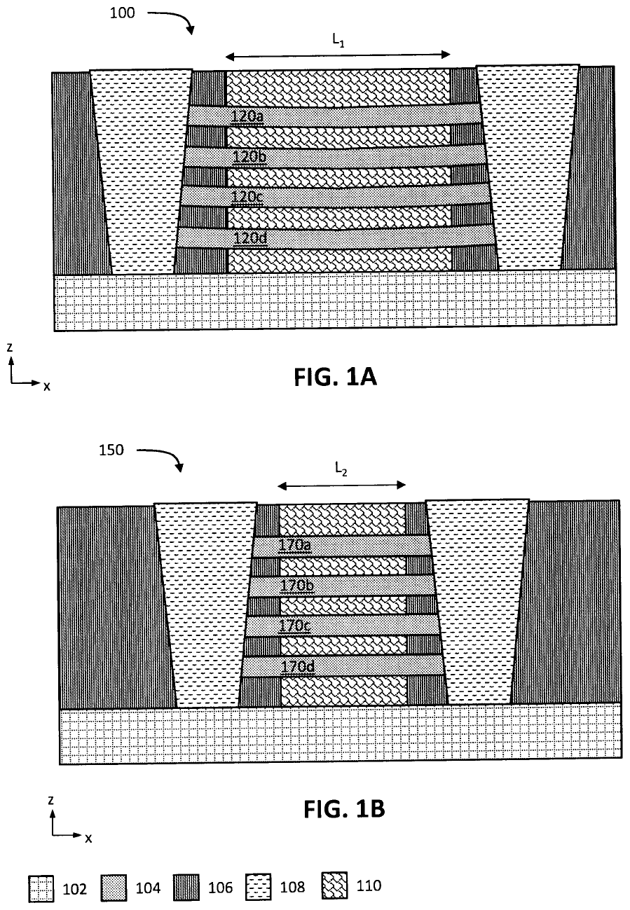

For convenience, if a collection of drawings designated with different letters are present, e.g., FIGS. 1A-1B, such a collection may be referred to herein without the letters, e.g., as “FIG. 1.”

### Example Long Channel and Short Channel Nanoribbon Transistors

FIGS. 1A-1B illustrate two example nanoribbon-based transistors having different channel lengths and gate lengths. FIG. 1A is a cross-section across a long-channel nanoribbon-based transistor 100 showing the source, gate, and drain. FIG. 1B is a cross-section across a short-channel nanoribbon-based transistor 150 showing the source, gate, and drain.

A number of elements referred to in the description of FIGS. 1A and 1B with reference numerals are illustrated in these figures with different patterns, with a legend at the bottom of the page showing the correspondence between the reference numerals and patterns. The legend illustrates that FIGS. 1A and 1B use different patterns to show a support structure 102, a channel material 104, a dielectric material 106, a source or drain (S/D) contact 108, and a gate electrode 110.

Each of the transistors 100 and 150 is formed over a respective support structure 102. Each transistor 100 and 150 includes a channel material 104 formed into four nanoribbons stacked on top of each other. The channel material 104 may be a semiconductor, such as silicon or other semiconductor materials described herein.

The transistor 100 includes nanoribbons 120a, 120b, 120c, and 120d, referred to collectively as nanoribbons 120 or individually as a nanoribbon 120. Each nanoribbon 120 is at a different height in the z-direction in the orientation shown in FIG. 1A. The transistor 150 includes nanoribbons 170a, 170b, 170c, and 170d. Each nanoribbon 170 is at a different height in the z-direction in the orientation shown in FIG. 1B. S/D contacts 108 are formed around either end of the nanoribbon channels 120 and 170, as illustrated in FIGS. 1A and 1B.

A central portion of each of the nanoribbon channels 120 and 170 is surrounded by a gate electrode 110. A gate dielectric, not specifically shown, may surround the nanoribbon channels under the gate electrodes 110. Regions of the nanoribbon channels 120 and 170 not surrounded by the gate electrode 110 or by an S/D contact 108 are filled in with a dielectric material 106.

The two transistors 100 and 150 have different channel lengths and different gate lengths. In FIG. 1A, the length L₁ represents the gate length of the transistor 100, and in FIG. 1B, the length L₂ represents the gate length of the transistor 150, where L₁ is longer than L₂. The channel length of the transistor 100, i.e., the length of the nanoribbons 120 in the x-direction in the orientation shown, is also greater than the channel length of the transistor 150, i.e., the length of the nanoribbons 170 in the x-direction in the orientation shown. Channel length and gate length are typically related, e.g., transistors with longer channels also have longer gates.

In FIG. 1B, the nanoribbons 170 extend straight through the gate electrode 110, parallel to the support structure 102 below the nanoribbons 170. In FIG. 1A, the nanoribbons 120 do not extend straight, but instead, bend or sag in their middles, e.g., in the section passing through the gate electrode 110. As described above, if a channel length is too long, the fabrication process can result in structural issues in the nanoribbons 120, causing the bending illustrated in FIG. 1A. During fabrication, the nanoribbons 120 are “released” from a surrounding supportive material (e.g., a sacrificial material), and temporarily “float” between structures at the ends of the nanoribbons 120, e.g., between the two S/D contacts 108 (if already formed) or between supporting dielectric material 106. After the release, a gate dielectric (not specifically illustrated in FIG. 1A) and the gate electrode 110 are grown around the semiconductor nanoribbons 120 to form the gate. During this process, long-channel nanoribbons tend to bend.

In addition, if the nanoribbons 120 are tightly spaced, this limits the thickness of the gate dielectric. For example, if adjacent nanoribbons 120 are 10 nanometers apart in the z-direction (e.g., there is a distance of 10 nanometers from the bottom of nanoribbon 120a to the top of nanoribbon 120b), a relatively thick gate dielectric would consume most or all of the space between adjacent nanoribbons 120. For example, a 4 nanometer thick gate dielectric grown on the bottoms and tops of the nanoribbons 120 leaves only 2 nanometers of space between adjacent nanoribbons 120 for the gate electrode to form. A 5 nanometer thick gate dielectric grown on the bottoms and tops of the nanoribbons 120 consumes all of the space between adjacent nanoribbons 120. If the nanoribbons 120 bend or sag during processing, this can further reduce the space between adjacent nanoribbons.

Thus, for circuit devices in which, for a portion of the transistors, a thicker gate dielectric (e.g., greater than 3 nanometers, 4 nanometers, 5 nanometers, 6 nanometers, 10 nanometers, etc.) is desired, it can be beneficial to use a different transistors architecture, e.g., a fin-shaped transistor. In addition, for circuit devices in which, for a portion of the transistors, a longer channel length (e.g., greater than 50 nanometers, greater than 100 nanometers, greater than 200 nanometers, or another length) is desired, it can be beneficial to use a different transistors architecture, e.g., a fin-shaped transistor. Such transistors may also have narrower channel widths, e.g., widths in the y-dimension in the orientation shown, than the nanoribbon transistors. The fin-shaped transistors described herein may be used in combination with shorter-channel nanoribbon transistors, e.g., the transistor 150 shown in FIG. 1A.

Example Process for Forming Device with Nanoribbon and Fin Transistors

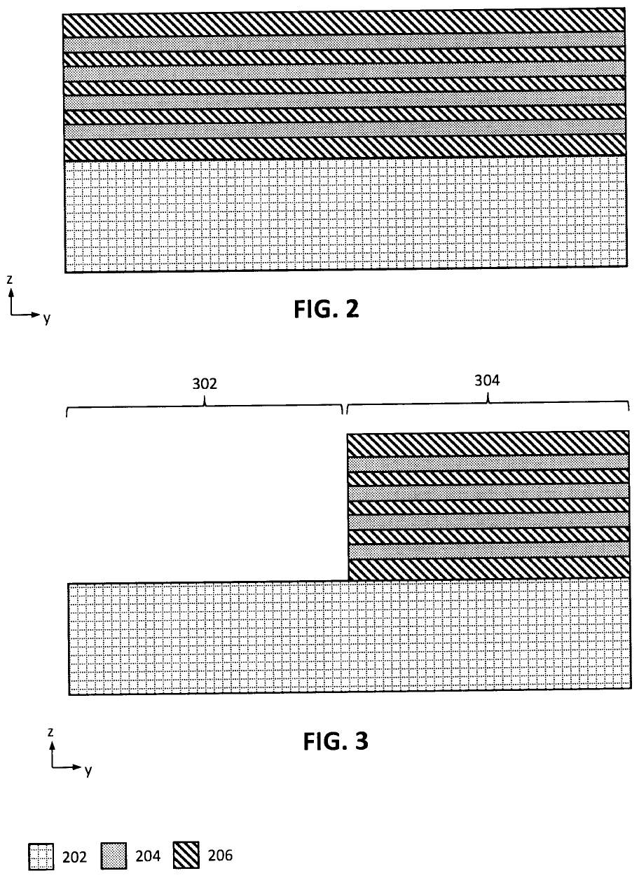

FIGS. 2-10 illustrate a process for forming integrated circuit devices that include a combination of fin transistors and nanoribbon transistors, e.g., fin transistors with longer channel lengths and thicker gate oxides, and nanoribbon transistors with shorter channel lengths and thinner gate oxides. FIGS. 11-14 provide additional embodiments and additional views of the IC devices.

A number of elements referred to in the description of FIGS. 2-14 with reference numerals are illustrated in these figures with different patterns, with a legend showing the correspondence between the reference numerals and patterns being provided at the bottom or side of each drawing page containing FIGS. 2-14. For example, the legend under FIGS. 2 and 3 illustrates that FIG. 2 uses different patterns to show a support structure 202, a channel material 204, and a sacrificial material 206.

In the drawings, some example structures of various devices and assemblies described herein are shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

FIG. 2 is a cross-section illustrating layers of alternating materials 204 and 206 formed over a support structure 202. In general, implementations of the present disclosure may be formed or carried out on a support structure 202, such as a semiconductor substrate composed of semiconductor material systems including, for example, N-type or P-type materials systems. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. Although a few examples of materials from which the substrate may be formed are described here, any material that may serve as a foundation upon which a semiconductor device may be built falls within the spirit and scope of the present disclosure. In various embodiments the support structure 202 may include any such substrate that provides a suitable surface for providing the nanoribbon transistors described herein, e.g., the transistors 700a and 700b illustrated in FIG. 7.

Alternating layers of a channel material 204 and a sacrificial material 206 are formed over the support structure 202. In general, to form nanoribbon channels, alternating layers of the channel material 204 and a sacrificial material 206 are deposited over the support structure 202. The channel material 204 and sacrificial materials 206 include different materials. In one example, the channel material 204 is silicon, while the sacrificial material 206 is a mixture of silicon and germanium. The sacrificial material 206 may be chosen to have a similar crystal structure to the channel material 204, so that monocrystalline layers of the channel material 204 (or substantially monocrystalline layers, e.g., with a grain size of at least 5 nanometers, at least 20 nanometers, at least 50 nanometers, or at least 100 nanometers) and monocrystalline layers of the sacrificial material 206 (or substantially monocrystalline layers) may be formed over each other. In different embodiments, the channel material 204 and/or the sacrificial material 206 may be formed of any suitable single-crystal material, such as sapphire, quartz, silicon, a compound of silicon (e.g., silicon oxide), indium phosphide, germanium or a germanium alloy (e.g., silicon germanium), gallium, arsenic (e.g., an arsenide III compound, where arsenic III is in combination with another element such as boron, aluminum, gallium, or indium), or any group III-V material (i.e., materials from groups III and V of the periodic system of elements).

More generally, the channel material 204 may be composed of semiconductor material systems including, for example, N-type or P-type materials systems. In other embodiments, the channel material 204 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. The channel material 204 may include one or more of cobalt oxide, copper oxide, ruthenium oxide, nickel oxide, niobium oxide, copper peroxide, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc.

In some embodiments, multiple channel materials may be included within an IC device. For example, an IC device may include both n-type metal-oxide-semiconductor (NMOS) transistors and p-type MOS (PMOS) transistors, e.g., alternating rows of NMOS and PMOS transistors. NMOS and PMOS logic can use different groups of channel material 204, e.g., silicon may be used to form an n-type semiconductor channel, while silicon germanium may be used as to form a p-type semiconductor channel. In some embodiments, a single channel material 204 is used (e.g., silicon), and different portions (e.g., channel material to form different transistors) may include different dopants, e.g., n-type dopants for NMOS transistors and p-type dopants for PMOS transistors.

FIG. 3 is a cross-section of the layers of alternating materials 204 and 206 with a region of the alternating materials 204 and 206 removed, according to some embodiments of the present disclosure. In FIG. 3, the left side of the layers of alternating materials shown in FIG. 2 has been removed, e.g., by etching. This region is labelled 302. In the region 304, the layers of alternating materials 204 and 206 remain. While FIG. 3 illustrates one region 302 of the layers of alternating materials being removed, across the support structure 202 (e.g., across a die or a wafer), multiple different regions of the alternating materials may be removed in regions where fin-shaped transistors are to be formed. Thus, FIG. 3 may illustrate one portion of the support structure, in which one region of the layers of alternating materials has been removed. The region 302 of alternating materials may be selected for removal using, e.g., a photolithographic process, where the alternating materials in the region 302 are patterned and then removed using an etching process (e.g., a wet etch or dry etch process). The alternating materials in the region 304 are protected, e.g., by a mask.

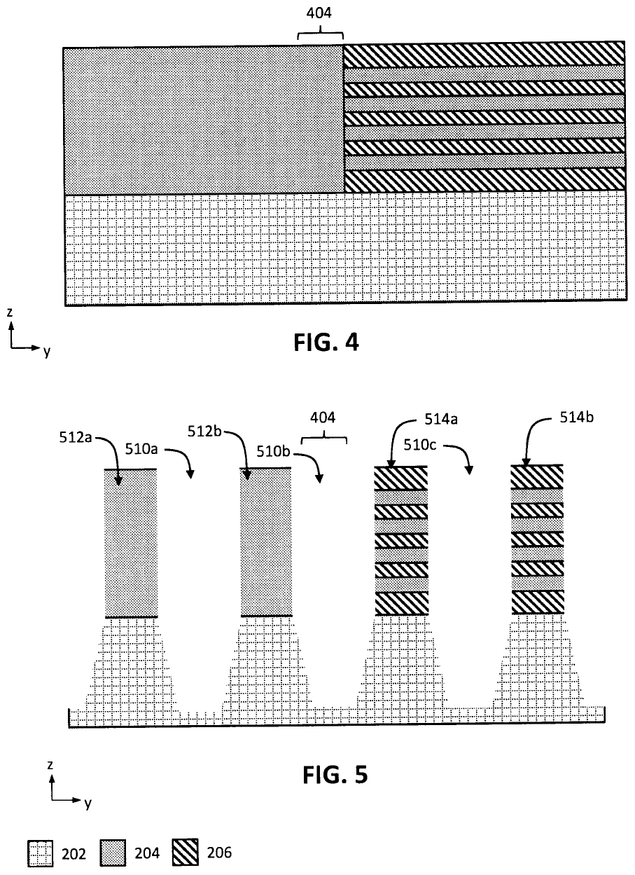

FIG. 4 is a cross-section illustrating a semiconductor material deposited next to the layers of alternating materials, according to some embodiments of the present disclosure. In FIG. 4, the region 302 of FIG. 3 has been filled by the channel material 204. For example, if the channel material 204 is silicon, silicon is epitaxially grown in the region 302. The channel material 204 may be a substantially monocrystalline material, as described above. The channel material 204 may have a consistent structure (e.g., a consistent lattice structure) when grown over the surface of the support structure 202. However, at a boundary between the newly-grown channel material 204 and the alternating layers in region 304, the structure of the newly-grown channel material 204 may have irregularities or defects. For example, in the region 404 labelled in FIG. 4, the channel material 204 may have defects, e.g., a greater number of defects than in the rest of the channel material 204 in the region 302, or a less consistent crystal structure. For example, the channel material 204 in the region 404 may appear amorphous or polycrystalline, while the channel material 204 in the rest of the region 302 may be monocrystalline. As another example, the channel material 204 in the region 404 may have a smaller grain size than the channel material 204 in the rest of the region 302. The region 404 may have a width (i.e., a dimension in the y-direction) of around, e.g., between 20 and 100 nanometers.

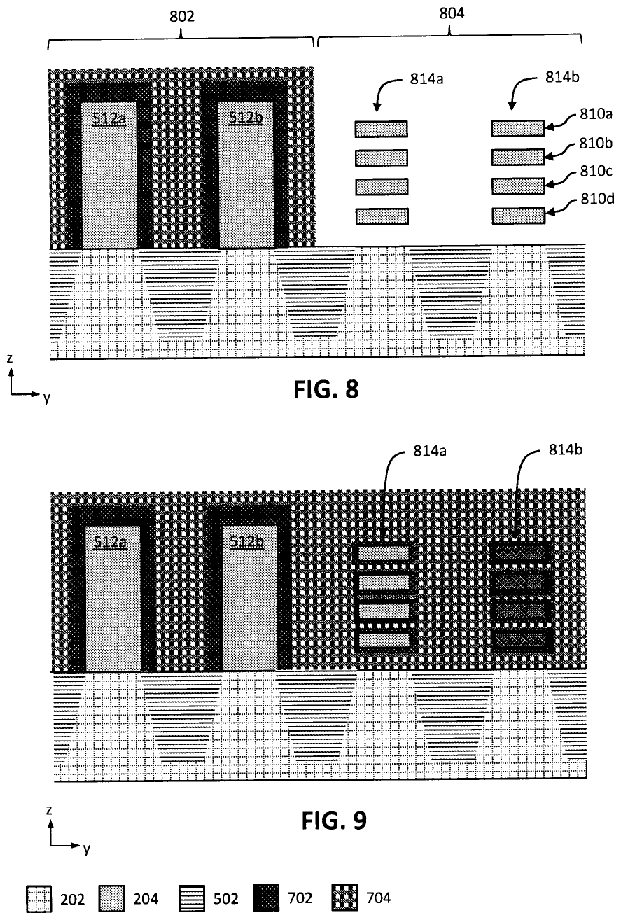

FIG. 5 is a cross-section illustrating etched rows of the semiconductor channel material 204 and stacks of alternating materials 204 and 206, according to some embodiments of the present disclosure. In FIG. 5, various regions of the channel materials 204 and alternating materials 204 and 206 have been removed, forming individuated fins 512a and 512b, and individuated nanoribbon stacks 514a and 514b. The nanoribbon stacks 514 include the sacrificial material 206 layered with the channel material 204; at a later processing stage (illustrated in FIG. 8 in this example, and discussed further below), the sacrificial material 206 is removed, releasing the nanoribbon channels formed by the channel material 204. The etched regions 510a-510c extend through respective portions of the channel materials 204 and layers of alternating materials 204 and 206, and extend into portions of the support structure 202. For example, the region 510a corresponds to a portion of the regrown channel material 204 in region 302 that has been etched away, and the region 510c corresponds to a portion of the layers of alternating materials 204 and 206 in region 304 that has been etched away. The region 510b corresponds to a portion of the regrown channel material 204 and an adjacent portion of the alternating materials 204 and 206. The region 510b includes the region 404, which may include defects or irregularities, as described above. For example, if the region 404 with defects is, e.g., 50 nanometers wide, the region 510b may have a width of at least, e.g., 100 nanometers, or at least 200 nanometers.

While FIG. 5 illustrates three regions 510 being removed, forming two fins 512a and 512b and two nanoribbon stacks 514a and 514b, across the support structure 202 (e.g., across a die or a wafer), many more fins 512 and nanoribbon stacks 514 may be formed. The regions 510 may be selected for removal using, e.g., a photolithographic process, where the channel materials in the regions 510 are removed using an etching process (e.g., a wet etch or dry etch process) and the fins 512 and nanoribbon stacks 514 are protected, e.g., by a mask.

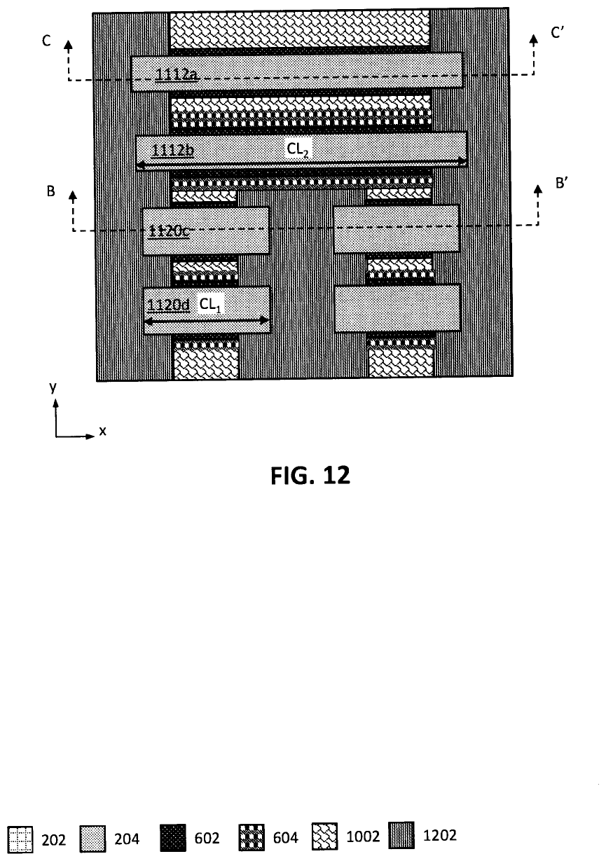

While the example in FIG. 5 illustrates the fins 512 and nanoribbon stacks 514 having the same or approximately the same width (the width being a dimension in the y-direction in the coordinate system shown), in other embodiments, the fins 512 and nanoribbon stacks 514 may have different widths, e.g., the fins 512 may be narrower than the nanoribbon stacks 514. An example of narrower fins and wider nanoribbons is illustrated in FIG. 11. In addition, the fins 512 and nanoribbon stacks 514 may have different channel lengths, where channel length is a length of the fins 512 and nanoribbon stacks 514 in the x-direction (e.g., into the page) in the coordinate system shown. For example, the fins 512 may have longer channel lengths than the nanoribbon stacks 514. An example of longer fins and shorter nanoribbons is illustrated in FIG. 12.

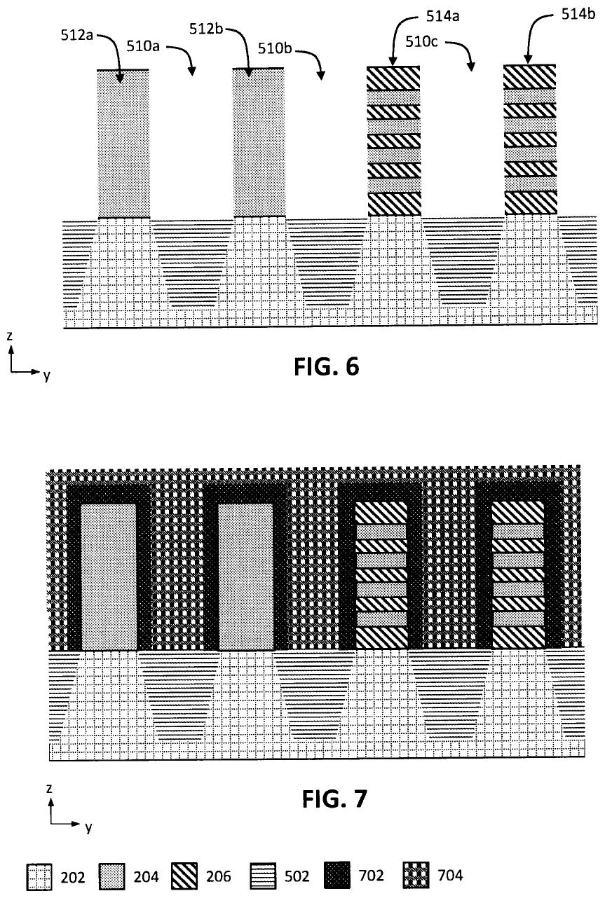

FIG. 6 is a cross-section illustrating dielectric fill in the support structure, according to some embodiments of the present disclosure. In FIG. 6, a dielectric material 602 has been added to the regions 510a-510c, and in particular, to fill in the portions of the support structure 202 that were etched in FIG. 5. The dielectric material 602 may be a trench isolation material, e.g., shallow trench isolation (STI). The dielectric material 602 may be a low-k or high-k dielectric including, but not limited to, any elements such as hafnium, silicon, oxygen, nitrogen, titanium, tantalum, lanthanum, aluminum, zirconium, barium, strontium, yttrium, lead, scandium, niobium, and zinc. Further examples of dielectric materials 602 include, but are not limited to, silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. The dielectric material 602 may be deposited using a physical deposition process, e.g., electron beam deposition or sputter deposition.

FIG. 7 is a cross-section illustrating deposition of thick gate dielectric and gate electrode material, according to some embodiments of the present disclosure. The gate dielectric 702 is deposited around each of the fins 512 and around each of the nanoribbon stacks 514. The gate dielectric 702 is formed over the top and along the sides of each of the fins 512 and each of the nanoribbon stacks 514. The gate electrodes 704 is then deposited around each of the fins 512 and each of the nanoribbon stacks 514, around the deposited gate dielectric 702.

The gate dielectric 702 may include one layer or a stack of layers, and the one or more layers may include silicon oxide, silicon dioxide, and/or a high-k dielectric material. The high-k dielectric material included in the gate dielectric layer 702 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 702 include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric 702 to improve its quality when a high-k material is used.

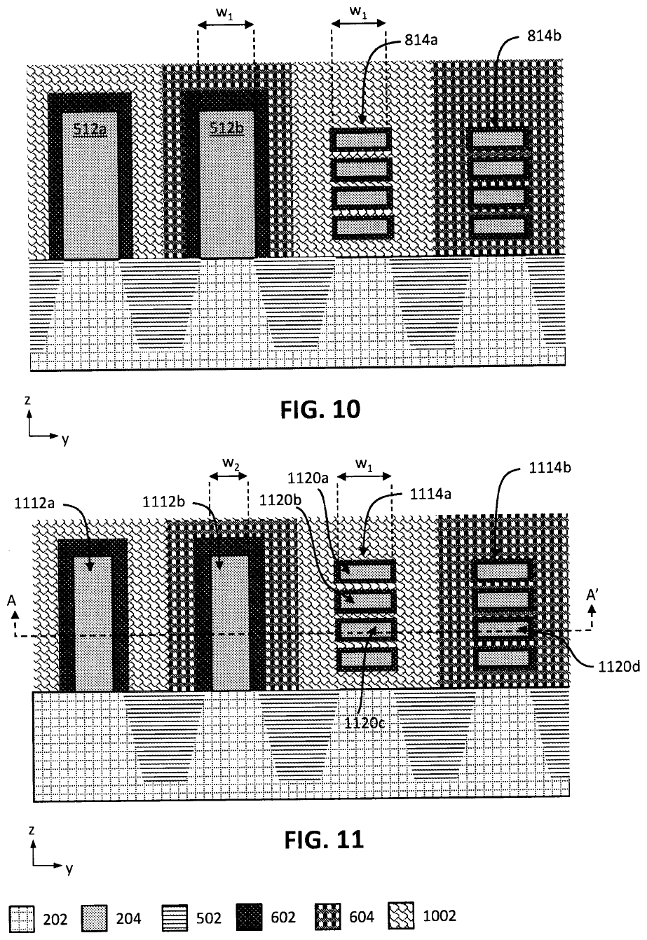

The gate electrode 704 may be a conductive material, such as a metal. In some embodiments, different gate electrode materials are used for different device types, e.g., an n-type work function metal for NMOS devices, and a p-type work function metal for PMOS devices. An example of replacing portions of the gate electrode 704 (e.g., an n-type work function metal) with a different gate electrode (e.g., a p-type work function metal) is described with respect to FIG. 10. The gate electrode 704 may include any of the electrode materials described with respect to FIG. 10.

A first processing step or sequence may be used to deposit the gate dielectric 702, and a second processing step or sequence may be used to deposit the gate electrode 704. The gate dielectric 702 may be deposited using a conformal deposition process, such as atomic layer deposition (ALD) or chemical vapor deposition (CVD). Conformal deposition generally refers to deposition of a certain coating on any exposed surface of a given structure. A conformal coating may, therefore, be understood as a coating that is applied to exposed surfaces of a given structure, and not, for example, just to the horizontal surfaces. The gate electrode 704 may be deposited using a conformal deposition process or a non-conformal deposition process, such as a physical deposition process.

In some embodiments, the nanoribbon stacks 514 illustrated in FIG. 6 are blocked (e.g., by a hard mask) during deposition of the gate dielectric 702 and gate electrode 704, rather than depositing the gate dielectric 702 and gate electrode 704 around the nanoribbon stacks 514. In this example, after the gate dielectric 702 and gate electrode 704 are deposited, nanoribbons are released from the nanoribbon stacks 514.

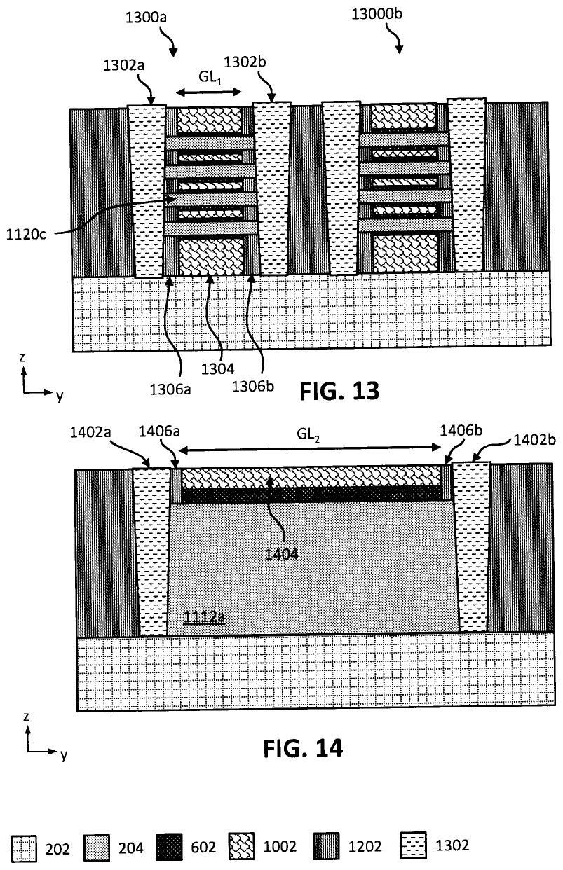

FIG. 8 is a cross-section illustrating releasing nanoribbons from the stacks of alternating materials, according to some embodiments of the present disclosure. In FIG. 8, in the region 804 (corresponding to the region 304 in FIG. 3), the gate electrode 704 and gate dielectric 702 are removed, e.g., using an etching process. If, as noted above, the nanoribbon stacks 514 are covered by a hard mask, the hard mask is removed, e.g., by etching. After the gate electrode 704 and gate dielectric 702 (or hard mask) are removed, the sacrificial material 206 between the channel material 204 in the stacks 514 is also etched, leaving two stacks 814a and 814b of released nanoribbons 810. For example, the released nanoribbon stack 814b includes a stack of four nanoribbons 810a, 810b, 810c, and 810d; the released nanoribbon stack 814a also includes four nanoribbons. The nanoribbons 810 may be supported at either end (e.g., one end into the page and another end out of the page in the x-direction in the orientation shown) by a dielectric material and/or S/D contact, e.g., the dielectric material illustrated in FIG. 12, or the S/D contacts illustrated in FIG. 13. After release, the nanoribbons 810 “float” between the two supported ends.

The sacrificial material 206 may be removed using an etching process, such as dry etch, wet etch, or a combination. An etchant material used to remove the sacrificial material 206 is selective to the channel material 204, i.e., the etchant removes the sacrificial material 206 but does not remove the channel material 204. The etchant material may also be selective to the gate electrode 704 over the fins 512. This process of removing the material around and between the nanoribbons 810 may be referred to as nanoribbon release.

After nanoribbon release, a gate dielectric 702 is deposited around each of the nanoribbons 810 in each of the released nanoribbon stacks 814, and a gate electrode 704 is deposited around and over the nanoribbons 810 and gate dielectric 702. FIG. 9 is a cross-section illustrating deposition of thin gate dielectric and gate electrode material around the nanoribbons, according to some embodiments of the present disclosure.

The gate dielectric 702 is formed over the top, along the sides, and along the bottoms of each of the nanoribbons 810. The gate dielectric 702 may be deposited using a conformal deposition process, such as the conformal deposition processes described with respect to FIG. 7. While the gate dielectric 702 around the nanoribbons 810 is illustrated as being the same gate dielectric as over the fins 512, in other embodiments, a different gate dielectric 702 is used for the nanoribbons 810. More generally, a gate dielectric around the nanoribbons may include any of the dielectric materials described with respect to the gate dielectric 702.

The gate dielectric around the nanoribbons 810 may be thinner than the gate dielectric over the fins 512. For example, the gate dielectric around the nanoribbons 810 may have a thickness of, e.g., less than 4 nanometers, less than 3 nanometers, less than 2 nanometers, or less than 1 nanometer. The gate dielectric over the fins 512 may have a thickness of, e.g., greater than 4 nanometers, greater than 5 nanometers, greater than 6 nanometers, greater than 10 nanometers, etc.

As noted above, in some embodiments, some portion of the transistors formed on the IC device are NMOS transistors, and another portion of the transistors formed on the IC device are PMOS transistors. In some embodiments, NMOS transistors and PMOS transistors are arranged in alternating rows. NMOS and PMOS transistors may use different materials systems, e.g., different channel materials, different dopants in the channel materials, different gate dielectric materials, and/or different gate electrode materials.

FIG. 10 is a cross-section illustrating different gate materials for different devices, according to some embodiments of the present disclosure. In FIG. 10, two portions of the gate electrode 704 (now referred to as the first gate electrode 704) around the fin 512a and around the nanoribbon stack 814a are removed and replaced by a second gate electrode 1002. For example, portions of the first gate electrode 704 over alternating rows of the fins 512 and nanoribbon stacks 814 may be patterned using photolithography, and portions of the first gate electrode 704 are removed, e.g., by etching. The second gate electrode 1002 is then deposited in the regions from which the gate electrode 704 was removed using a conformal or non-conformal deposition process, as described above.

The first gate electrode 704 and second gate electrode 1002 may be different electrode materials. For example, the first gate electrode 704 may be a metal having a p-type work function, while the second gate electrode 1002 may be a metal having an n-type work function. For a PMOS transistor, the gate electrode 704 may include, but is not limited to, ruthenium, palladium, platinum, cobalt, nickel, and conductive metal oxides (e.g., ruthenium oxide). For an NMOS transistor, the gate electrode 1002 may include, but is not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). Other materials that may be used include titanium nitride, tantalum nitride, hafnium nitride, tungsten, iridium, copper, or degenerately doped poly-silicon. In some embodiments, one or both of the gate electrodes 704 or 1002 may consist of a stack of two or more metal layers, where one or more metal layers are work function metal layers and at least one metal layer is a fill metal layer.

In the example shown in FIG. 10, the nanoribbons 810 in the nanoribbon stacks 814 have a same width as the fins 512. For example, the fin 512b is illustrated as having a w₁ in FIG. 10, where the width w₁ is a dimension in the y-direction, parallel to the support structure 202 and perpendicular to the direction in which the fin 512b primarily extends (i.e., the x-direction in the coordinate system shown). The nanoribbons in the stack 814a are also illustrated as having the same width w₁.

Additional Examples and Views of IC Devices with Nanoribbon and Fin Transistors

In the example shown in FIGS. 2-10, the nanoribbons and fins had the same width. In some embodiments, the nanoribbons and fins may have different widths. A similar process may be used to produce a device with different-width nanoribbons and fins.

FIG. 11 is a cross-section illustrating differing widths for fin and nanoribbon structures, according to some embodiments of the present disclosure. For example, the fin 1112b has a width w₂, and the nanoribbons in the nanoribbon stack 1114a (e.g., nanoribbons 1120a, 1120b) have a width w₁, where w₁ is greater than w₂. The fin 1112a may also have the width w₂, and the nanoribbons in the nanoribbon stack 1114b may also have the width w₁. The fin width w₂ may be, for example, between 1 nanometers and 10 nanometers, while the nanoribbon width w₁ may be, for example, between 10 nanometers and 50 nanometers.

The nanoribbons and fins also have different heights, where height is a dimension in the z-direction in the coordinate system shown. The height is in a direction perpendicular to the support structure 202. The fins 1112 may have a height that is multiple times the height of the nanoribbons 1120, e.g., at least five times, at least ten times, or at least 20 times. In the example shown, an upper surface of the fins 1112 is above an upper surface of the highest nanoribbons (e.g., the top surface of the nanoribbon 1120a), and a lower surface of the fins 1112 is below a bottom surface of the lowest nanoribbons 1120. In various embodiments, the nanoribbons 1120 have a height of less than 10 nanometers, less than 8 nanometers, less than 5 nanometers, less than 4 nanometers, less than 3 nanometers, etc. The fins 1112 may have a height of, e.g., at least 20 nanometers, at least 30 nanometers, at least 50 nanometers, at least 75 nanometers, etc.

FIG. 12 illustrates a cross-section of the fins and nanoribbons through the plane AA′ in FIG. 11, according to some embodiments of the present disclosure. FIG. 12 illustrates a cross-section through the fins 1112a and 1112b, and the nanoribbons 1120c and 1120d.

FIG. 12 shows that the nanoribbons 1120 and fins 1112 each have an elongated structure that extends over the support structure 202. Each nanoribbon 1120 extends primarily in the x-direction in the coordinate system used in FIGS. 2-14. Each fin 1112 also extends primarily in the x-direction in the coordinate system used in FIGS. 2-14. The direction in which the nanoribbons 1120 and fins 1112 extend is parallel to the support structure 202.

FIG. 12 illustrates different channel lengths CL of the fin channels and nanoribbon channels. A nanoribbon channel length CL₁ of the nanoribbon 1120d and a fin channel length CL₂ of the fin 1112b are illustrated. The fin channel length CL₂ is longer than the nanoribbon channel length CL₁. For example, the fin channel length CL₂ may be at least twice the nanoribbon channel length CL₁, or at least at least three times the nanoribbon channel length CL₁. The nanoribbon channel length CL₁ may be, e.g., less than 100 nanometers (e.g., between 50 and 100 nanometers), less than 50 nanometers (e.g., between 25 and 50 nanometers), or less than 30 nanometers (e.g., between 10 and 30 nanometers). The fin channel length CL₂ may be, e.g., at least 20 nanometers (e.g., between 20 and 40 nanometers), at least 40 nanometers (e.g., between 40 and 80 nanometers), at least 50 nanometers (e.g., between 50 and 90 nanometers), at least 100 nanometers (e.g., between 100 and 200 nanometers), etc.

The transistors illustrated in FIG. 12 are surrounded by a dielectric material 1202, which provides electrical isolation. While one dielectric material 1202 is shown in FIG. 12, different regions or layers of dielectric material may be used in or around different parts of the device.

FIG. 13 illustrates a cross-section of two nanoribbon transistors through the plane BB′ in FIG. 12, according to some embodiments of the present disclosure. The nanoribbon 1120c, also labelled in FIGS. 11 and 12, is labelled in FIG. 13. FIG. 13 is a cross-section through two stacks of nanoribbon channels, as well as the source, gate, and drain formed around the nanoribbon channels, forming two transistors 1300a and 1300b.

For example, the transistor 1300a includes a first S/D contact 1302a, a second S/D contact 1302b, and a channel region formed form the nanoribbons 1120, e.g., the nanoribbon 1120c. As shown in FIGS. 11 and 12, a gate electrode 1304 is around and between the nanoribbons 1120. A cross-section of the transistor 1300b has a similar appearance and similar components. The transistors illustrated in FIG. 13 are surrounded by the dielectric material 1202. For example, two dielectric region 1306a and 1306b electrically isolate the gate electrode 1304 from the S/D contacts 1302a and 1302b, respectively.

The S/D contacts 1302a and 1302b are formed around opposite ends of the nanoribbon channels. The S/D contacts 1302 may be formed from one or more layers of metal and/or metal alloys. The S/D contacts 1302 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the S/D contacts 1302 may include one or more electrically conductive alloys, oxides, or carbides of one or more metals. In some embodiments, the S/D contacts 1302 may include a doped semiconductor, such as silicon or another semiconductor doped with an N-type dopant or a P-type dopant. Metals may provide higher conductivity, while doped semiconductors may be easier to pattern during fabrication. In some embodiments, the S/D contacts 1302 may include both a semiconductor and a metal, e.g., an atomic layer deposition (ALD)-deposited doped oxide semiconductor followed by metal.

FIG. 13 illustrates a gate length GL₁ of the transistor 1300a. The transistor 1300b may have a similar gate length. The gate length GL₁ is less than the channel length CL₁. The gate length GL₁ of the nanoribbon transistors 1300 may be, for example, less than 100 nanometers (e.g., between 40 and 90 nanometers), less than 50 nanometers (e.g., between 20 and 50 nanometers), or less than 30 nanometers (e.g., between 5 and 30 nanometers).

FIG. 14 illustrates a cross-section of a fin transistor through the plane CC′ in FIG. 12, according to some embodiments of the present disclosure. The fin 1112a, also labelled in FIGS. 11 and 12, is labelled in FIG. 14. FIG. 14 is a cross-section through one of the fin channels, as well as the source, gate, and drain formed around the fin channel, forming a transistor.

The transistor of FIG. 14 includes a first S/D contact 1402a, a second S/D contact 1402b, and a channel region formed form the fin 1112a. As shown in FIGS. 11 and 12, a gate electrode 1404 is formed over the top of and around the side of the fin 1112a. The components illustrated in FIG. 14 are surrounded by the dielectric material 1202. For example, two dielectric region 1406a and 1406b electrically isolate the gate electrode 1404 from the S/D contacts 1402a and 1402b, respectively. The S/D contacts 1402a and 1402b may be similar to the S/D contacts 1302a and 1302b, described above.

FIG. 14 illustrates a gate length GL₂ of the fin transistor. The gate length GL₂ is less than the channel length CL₂. The gate length GL₂ of the fin transistors may be, for example, at least 10 nanometers (e.g., between 10 and 40 nanometers), at least 30 nanometers (e.g., between 30 and 50 nanometers), at least 50 nanometers (e.g., between 50 and 100 nanometers), at least 100 nanometers (e.g., between 100 and 200 nanometers), etc. The gate length GL₂ of the fin transistors is longer than (i.e., greater than) the gate length GL₁ of the nanoribbon transistors. For example, GL₂ may be at least two times, at least three times, or at least four times as large as GL₁.

### Example Devices

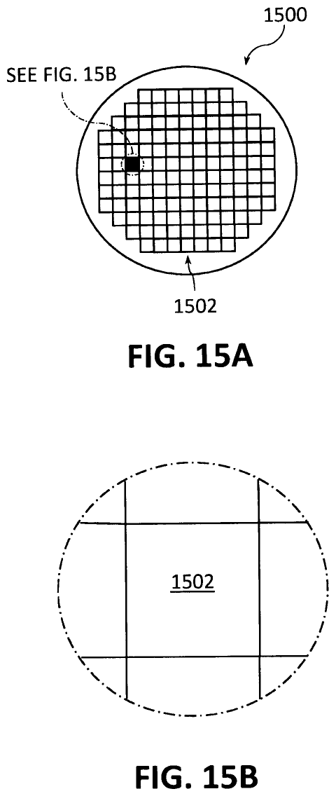

The circuit devices with one or more fin transistors along with nanoribbon transistors disclosed herein may be included in any suitable electronic device. FIGS. 15-18 illustrate various examples of apparatuses that may include the one or more fin transistors along with nanoribbon transistors disclosed herein.

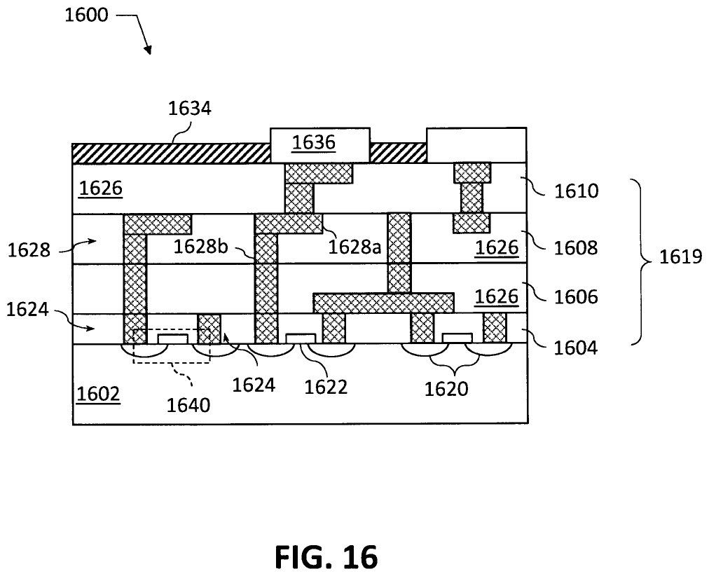

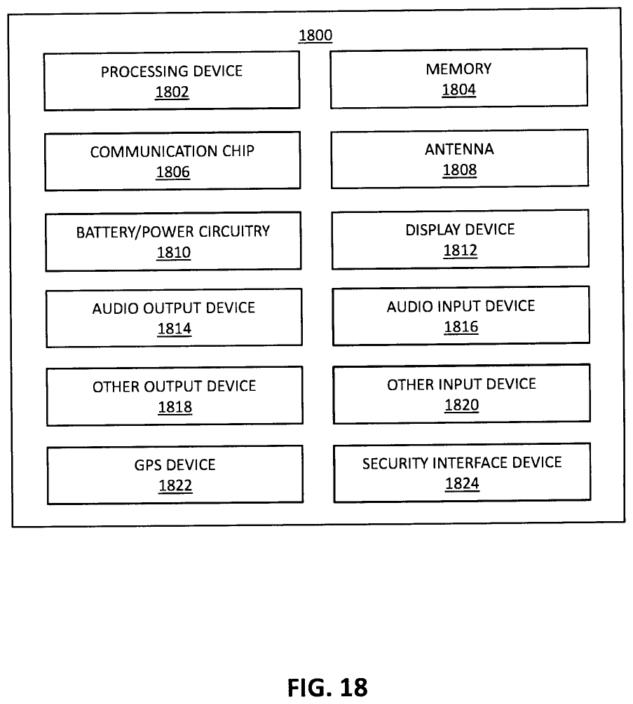

FIGS. 15A and 15B are top views of a wafer and dies that include one or more IC structures including one or more fin transistors along with nanoribbon transistors in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 2-14, or any further embodiments of the IC structures described herein). After the fabrication of the semiconductor product is complete (e.g., after manufacture of one or more IC structures with one or more fin transistors along with nanoribbon transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more fin transistors along with nanoribbon transistors as disclosed herein may take the form of the wafer 1500 (e.g., not singulated) or the form of the die 1502 (e.g., singulated). The die 1502 may include one or more transistors (e.g., one or more of the transistors 1640 of FIG. 16, discussed below) and/or supporting circuitry to route electrical signals to the transistors, as well as any other IC components (e.g., one or more fin transistors along with nanoribbon transistors). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 18) or other logic that is configured to store information in the memory devices or execute instructions stored in the memory array.

FIG. 16 is a cross-sectional side view of an IC device 1600 that may include one or more fin transistors along with nanoribbon transistors in accordance with any of the embodiments disclosed herein. The IC device 1600 may be formed on a substrate 1602 (e.g., the wafer 1500 of FIG. 15A) and may be included in a die (e.g., the die 1502 of FIG. 15B). The substrate 1602 may be any substrate as described herein. The substrate 1602 may be part of a singulated die (e.g., the dies 1502 of FIG. 15B) or a wafer (e.g., the wafer 1500 of FIG. 15A).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 16 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more fin transistors along with nanoribbon transistors at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 16 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 16). Although a particular number of interconnect layers 1606-1610 is depicted in FIG. 16, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 16. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 16. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

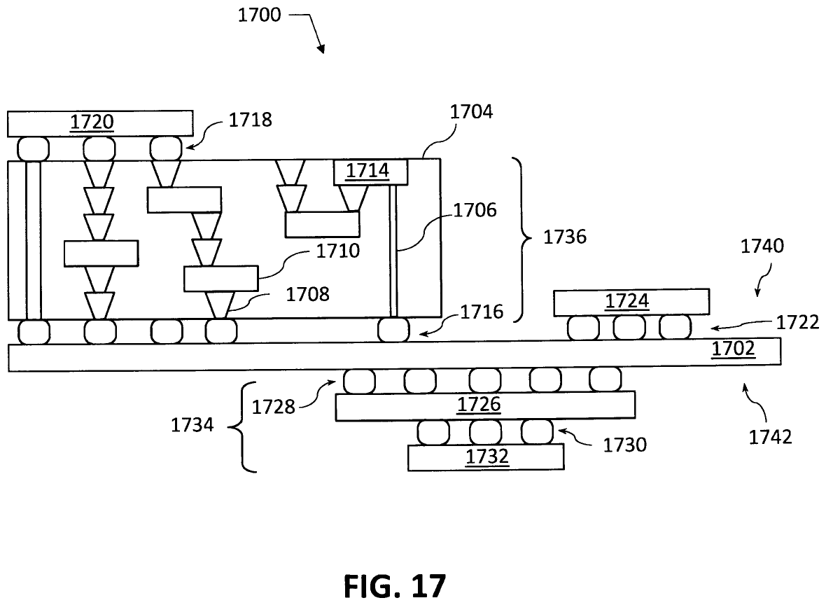

FIG. 17 is a cross-sectional side view of an IC device assembly 1700 that may include components having or being associated with (e.g., being electrically connected by means of) one or more fin transistors along with nanoribbon transistors in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more fin transistors along with nanoribbon transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 17 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 17), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 17, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 15B), an IC device (e.g., the IC device 1600 of FIG. 16), or any other suitable component. In some embodiments, the IC package 1720 may include one or more fin transistors along with nanoribbon transistors, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 17, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 17 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 18 is a block diagram of an example computing device 1800 that may include one or more components including one or more fin transistors along with nanoribbon transistors in accordance with any of the embodiments disclosed herein. For example, any suitable ones of the components of the computing device 1800 may include a die (e.g., the die 1502 of FIG. 15B) having one or more fin transistors along with nanoribbon transistors as described herein. Any one or more of the components of the computing device 1800 may include, or be included in, an IC device 1600 (FIG. 16). Any one or more of the components of the computing device 1800 may include, or be included in, an IC device assembly 1700 (FIG. 17).

A number of components are illustrated in FIG. 18 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 17, but the computing device 1800 may include interface circuitry for coupling to the one or more components. For example, the computing device 1800 may not include a display device 1806, but may include display device interface circuitry (e.g., a connector and driver circuitry) to which a display device 1806 may be coupled. In another set of examples, the computing device 1800 may not include an audio input device 1824 or an audio output device 1808 but may include audio input or output device interface circuitry (e.g., connectors and supporting circuitry) to which an audio input device 1824 or audio output device 1808 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the computing device 1800 may include a communication chip 1812 (e.g., one or more communication chips). For example, the communication chip 1812 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The computing device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The computing device 1800 may include battery/power circuitry 1814. The battery/power circuitry 1814 may include one or more energy storage devices (e.g., batteries or capacitors) and/or circuitry for coupling components of the computing device 1800 to an energy source separate from the computing device 1800 (e.g., AC line power).

The computing device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1808 (or corresponding interface circuitry, as discussed above). The audio output device 1808 may include any device that generates an audible indicator, such as speakers, headsets, or earbuds, for example.

The computing device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The computing device 1800 may include a GPS device 1818 (or corresponding interface circuitry, as discussed above). The GPS device 1818 may be in communication with a satellite-based system and may receive a location of the computing device 1800, as known in the art.

The computing device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The computing device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### Select Examples

The following paragraphs provide various examples of the embodiments disclosed herein.

Example 1 provides an IC device including a substrate; a first elongated structure (e.g., a first nanoribbon) over the substrate, the first elongated structure extending in a first direction parallel to the substrate, the first elongated structure having a first length in the first direction, and the first elongated structure having a height less than 5 nanometers; and a second elongated structure (e.g., a first fin) over the substrate, the second elongated structure extending in the first direction and the second elongated structure further parallel to the first elongated structure, the second elongated structure having a second length in the first direction, the second length greater than the first length.

Example 2 provides the IC device of example 1, where the second elongated structure is a fin having a height greater than 20 nanometers.

Example 3 provides the IC device of example 2, further including a third elongated structure (e.g., a second nanoribbon) over the first elongated structure, the third elongated structure having the first length and extending in the first direction.

Example 4 provides the IC device of any of examples 1-3, where the second length is at least twice the first length.

Example 5 provides the IC device of any of examples 1-4, where the first elongated structure has a first width and the second elongated structure has a second width, the first width greater than the second width.

Example 6 provides the IC device of example 5, where the first width is at least 10 nanometers.

Example 7 provides the IC device of example 5 or 6, where the second width is less than 6 nanometers.

Example 8 provides an IC device including a semiconductor nanoribbon extending in a first direction; a first dielectric surrounding a portion of the semiconductor nanoribbon, the first dielectric having a first thickness; a semiconductor fin extending in the first direction and parallel to the semiconductor nanoribbon; and a second dielectric over a portion of the semiconductor fin, the second dielectric having a second thickness, the second thickness greater than the first thickness.

Example 9 provides the IC device of example 8, where, in a cross-section through the semiconductor fin, the second dielectric is over a top of the semiconductor fin and along sides of the semiconductor fin.

Example 10 provides the IC device of example 8 or 9, where a first gate metal is formed around the first dielectric, and a second gate metal is formed around the second dielectric.

Example 11 provides the IC device of example 10, where the semiconductor fin and the semiconductor nanoribbon include different semiconductor materials, and the first gate metal and the second gate metal include different metal materials. (e.g., fin is PMOS and nanoribbon is NMOS, or vice versa)

Example 12 provides the IC device of example 10 or 11, the first gate metal having a first length in the first direction, the second gate metal having a second length in the first direction, the second length greater than the first length.

Example 13 provides the IC device of example 12, where the second length is at least twice the first length.

Example 14 provides the IC device of any of examples 8-13, further including a second semiconductor nanoribbon stacked over the semiconductor nanoribbon, the second semiconductor nanoribbon surrounded by the first dielectric.

Example 15 provides the IC device of example 14, where a gate metal is between the first dielectric around the semiconductor nanoribbon and the first dielectric around the second semiconductor nanoribbon.

Example 16 provides the IC device of any of examples 8-15, the semiconductor nanoribbon having a first length in the first direction, the semiconductor fin having a second length in the first direction, the second length greater than the first length.

Example 17 provides the IC device of example 16, where the second length is at least twice the first length.

Example 18 provides a device including a first transistor including a stack of nanoribbons, each nanoribbon of the stack of nanoribbons extending in a first direction, the stack of nanoribbons having a first length in the first direction; and a second transistor including a fin, the fin extending in the first direction and parallel to the stack of nanoribbons, the fin having a second length in the first direction, the second length greater than the first length.

Example 19 provides the device of example 18, the stack of nanoribbons having a first width, the fin having a second width, the second width less than the first width.

Example 20 provides the device of example 18 or 19, the first transistor including a first dielectric having a first thickness, the second transistor including a second dielectric having a second thickness, the second thickness greater than the first thickness.

Example 21 provides an IC package that includes an IC die, including one or more of the IC devices according to any one of the preceding examples. The IC package may also include a further component, coupled to the IC die.

Example 22 provides the IC package according to example 21, where the further component is one of a package substrate, a flexible substrate, or an interposer.

Example 23 provides the IC package according to examples 21 or 22, where the further component is coupled to the IC die via one or more first level interconnects.

Example 24 provides the IC package according to example 23, where the one or more first level interconnects include one or more solder bumps, solder posts, or bond wires.

Example 25 provides a computing device that includes a circuit board; and an IC die coupled to the circuit board, where the IC die includes one or more of the transistor/IC devices according to any one of the preceding examples (e.g., transistor/IC devices according to any one of examples 1-20), and/or the IC die is included in the IC package according to any one of the preceding examples (e.g., the IC package according to any one of examples 21-24).

Example 26 provides the computing device according to example 25, where the computing device is a wearable computing device (e.g., a smart watch) or hand-held computing device (e.g., a mobile phone).

Example 27 provides the computing device according to examples 25 or 26, where the computing device is a server processor.

Example 28 provides the computing device according to examples 25 or 26, where the computing device is a motherboard.

Example 29 provides the computing device according to any one of examples 25-28, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device comprising:
a substrate;
a first elongated structure over the substrate, the first elongated structure extending in a first direction parallel to the substrate, the first elongated structure having a first length in the first direction, and the first elongated structure having a height less than 5 nanometers; and
a second elongated structure over the substrate, the second elongated structure extending in the first direction and the second elongated structure further parallel to the first elongated structure, the second elongated structure having a second length in the first direction, the second length greater than the first length.

2. The IC device of claim 1, wherein the second elongated structure is a fin having a height greater than 20 nanometers.

3. The IC device of claim 2, further comprising a third elongated structure over the first elongated structure, the third elongated structure having the first length and extending in the first direction.

4. The IC device of claim 1, wherein the second length is at least twice the first length.

5. The IC device of claim 1, wherein the first elongated structure has a first width and the second elongated structure has a second width, the first width greater than the second width.

6. The IC device of claim 5, wherein the first width is at least 10 nanometers.

7. The IC device of claim 5, wherein the second width is less than 6 nanometers.

8. An integrated circuit (IC) device comprising:
a semiconductor nanoribbon extending in a first direction;
a first dielectric surrounding a portion of the semiconductor nanoribbon, the first dielectric having a first thickness;
a semiconductor fin extending in the first direction and parallel to the semiconductor nanoribbon; and
a second dielectric over a portion of the semiconductor fin, the second dielectric having a second thickness, the second thickness greater than the first thickness.

9. The IC device of claim 8, wherein, in a cross-section through the semiconductor fin, the second dielectric is over a top of the semiconductor fin and along sides of the semiconductor fin.

10. The IC device of claim 8, wherein a first gate metal is formed around the first dielectric, and a second gate metal is formed around the second dielectric.

11. The IC device of claim 10, wherein the semiconductor fin and the semiconductor nanoribbon comprise different semiconductor materials, and the first gate metal and the second gate metal comprise different metal materials.

12. The IC device of claim 10, the first gate metal having a first length in the first direction, the second gate metal having a second length in the first direction, the second length greater than the first length.

13. The IC device of claim 12, wherein the second length is at least twice the first length.

14. The IC device of claim 8, further comprising a second semiconductor nanoribbon stacked over the semiconductor nanoribbon, the second semiconductor nanoribbon surrounded by the first dielectric.

15. The IC device of claim 14, wherein a gate metal is between the first dielectric around the semiconductor nanoribbon and the first dielectric around the second semiconductor nanoribbon.

16. The IC device of claim 8, the semiconductor nanoribbon having a first length in the first direction, the semiconductor fin having a second length in the first direction, the second length greater than the first length.

17. The IC device of claim 16, wherein the second length is at least twice the first length.

18. A device comprising:
a first transistor comprising a stack of nanoribbons, each nanoribbon of the stack of nanoribbons extending in a first direction, the stack of nanoribbons having a first length in the first direction; and
a second transistor comprising a fin, the fin extending in the first direction and parallel to the stack of nanoribbons, the fin having a second length in the first direction, the second length greater than the first length.

19. The device of claim 18, the stack of nanoribbons having a first width, the fin having a second width, the second width less than the first width.

20. The device of claim 18, the first transistor comprising a first dielectric having a first thickness, the second transistor comprising a second dielectric having a second thickness, the second thickness greater than the first thickness.
